(19) United States
(12) Patent Application Publication
(10) Pub. No.: US 2005/0270741 A1
(43) Pub. Date: Dec. 8, 2005

(54) Large-area planar heat dissipation structure

(76) Inventors: Chin Wen Wang, Pingjhen City (TW); Pei Choa Wang, Pingjhen City (TW); Ching Chung Wang, Pingjhen City (TW)

Correspondence Address: Yi-Wen Tseng, 4331 Stevens Battle Lane, Fairfax, VA, 22033, US

(21) Appl. No.: 10/858,066

(22) Filed: Jun. 2, 2004

(51) Int. Cl. H05K 7/20

(52) U.S. Cl. 361/695

(57) ABSTRACT

A large-area heat dissipation structure has a thermal conducting member and a heat sink assembly. The thermal conducting member has a large-area thermal conductive plate and a thermal conductive base protruding from a lower surface of the large-area thermal conductive plate. The heat sink assembly has a plurality of fins mounted to an upper surface of the thermal conducting member. A plurality of support members extends downwardly from the lower surface of the large-area thermal conductive plate.

### BACKGROUND OF THE INVENTION

The present invention relates in general to a large-area planar heat dissipation structure, and more particularly, to an elevated planar heat dissipation structure installed in a housing of a semiconductor device. The elevated planar heat dissipation structure has a large-area heat dissipation member in which more heat sinks can be installed to provide more than one heat dissipation surfaces. Thereby, heat dissipation performance is enhanced.

Integrated circuits or other electronic devices are typically mounted on a circuit board such as a printed circuit board. The printed circuit board is then enclosed in a housing. The continuous development of electronic circuit and integrated circuit technologies provides faster operation and processing speed. To obtain more functionality in a single circuit board, more electronic devices are integrated thereon. Consequently, an efficient heat dissipation apparatus is required.

Fans have been mounted in the housing of an electronic product to guide external air into therein, so as to dissipate heat generated by the electronic product. However, as the one-way air circulation is not efficient enough for modern electronics, heat dissipation devices for heat removal have been proposed. Such heat dissipation device includes a thermal conductive base and heat sinks mounted to the thermal conductive base. The thermal conductive base is in contact with a heat generating source for delivering heat generated thereby, while the heat sinks serve to dissipate heat delivered from the thermal conductive base. This type of heat dissipation device is frequently used in combination with the fan to further improve heat dissipation efficiency.

The above heat dissipation device has a heat dissipation area limited by the available space in the housing, particularly in a compact device. The limited heat dissipation area seriously affects the heat dissipation efficiency of the heat dissipation device.

### BRIEF SUMMARY OF THE INVENTION

The present invention provides a large-area heat dissipation structure, comprising a thermal conducting member and a heat sink assembly. The thermal conducting member has a large-area thermal conductive plate and a thermal conductive base protruding from a lower surface of the large-area thermal conductive plate. The heat sink assembly has a plurality of fins mounted to an upper surface of the thermal conducting member. A plurality of support members extends downwardly from the lower surface of the large-area thermal conductive plate. Each of the support members terminates with a fastening member. Preferably, the large-area thermal conductive plate includes a large-area uniform thermal board. The thermal conductive base includes a uniform thermal cylinder. The large-area thermal conductive plate and the thermal conductive base can be formed integrally or from separate members joined together. The large-area thermal conductive plate may include an upper thermal conductive plate and a lower thermal conductive plate joined together. A wind generating device may be installed at one side of the heat sink assembly.

The present invention further provides a large-area planar heat dissipation structure to dissipate heat generated from an electronic device mounted on a circuit board. The structure comprises a thermal conducting member and a heat sink assembly. The thermal conducting member includes a thermal conductive plate elevated over the electronic device and a thermal conductive base extending downwardly from the thermal conductive plate. The heat sink assembly is attached on the thermal conductive member. The thermal conducting member further comprises a plurality of support members extending downwardly therefrom. The support members are fastened to the circuit board. The thermal conductive base has a bottom surface conformal to a top surface of the electronic device. The thermal conductive base is in direct contact with the electronic device. The thermal conductive plate comprises a large-area upper plate and a large-area lower plate joined together. The heat sink assembly comprises a plurality of fins. The structure further comprises a fan installed at one side of the thermal conducting member.

The present invention also provides an electronic product comprising the following members. A circuit board is enclosed in a housing, and an electronic device is mounted on the circuit board. A heat dissipation device is disposed over the circuit board in the housing for dissipation heat generated by the electronic device. The heat dissipation device includes a thermal conducting member having a large-area thermal conductive plate elevated over the electronic device and a thermal conductive member extending downwardly from the thermal conductive plate. The thermal conductive base is in direct contact with the electronic device. A heat sink assembly is attached on the thermal conducting member. A fan can also be mounted at one side of the heat dissipation device in the housing.

### BRIEF DESCRIPTION OF THE DRAWINGS

The above objects and advantages of the present invention will be become more apparent by describing in detail exemplary embodiments thereof with reference to the attached drawings in which:

FIG. 1 is an exploded view of one embodiment of a heat dissipation device;

FIG. 2 is a cross sectional view of the heat dissipation device as shown in FIG. 1;

FIG. 3 is a bottom view of the heat dissipation device as shown in FIG. 1;

FIG. 4 is a cross sectional view of assembly of the heat dissipation device with an electronic device;

FIG. 5 illustrates the application of the heat dissipation device in a computer host;

FIG. 6 shows a dual-platform assembly of the heat dissipation device; and

FIG. 7 is a cross sectional view of another embodiment of a heat dissipation device.

### DETAILED DESCRIPTION OF THE INVENTION

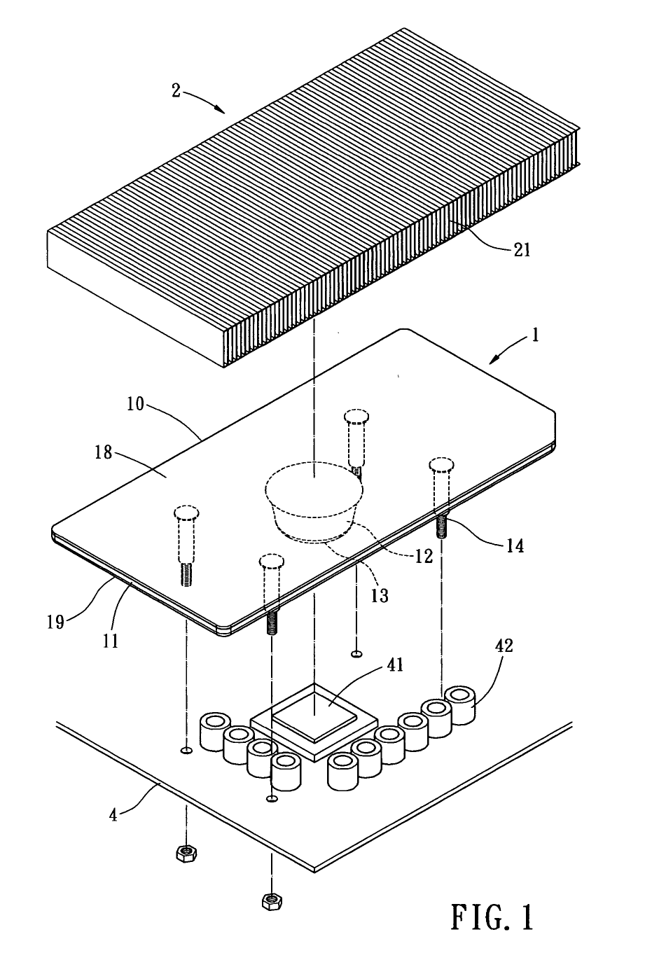

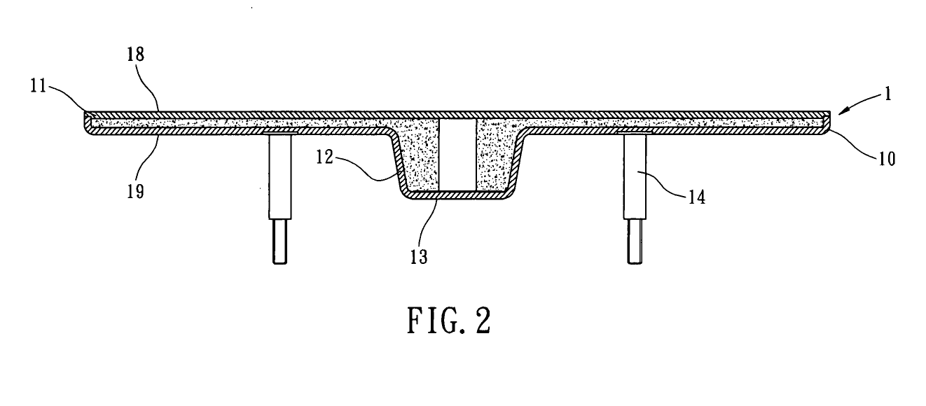

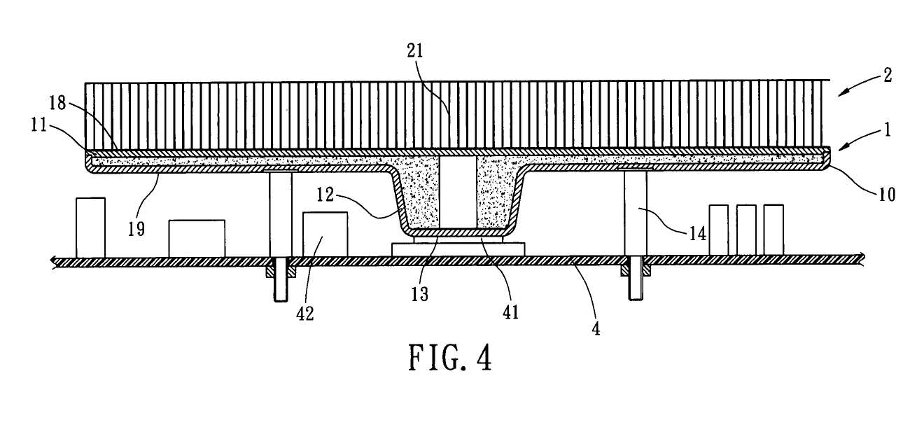

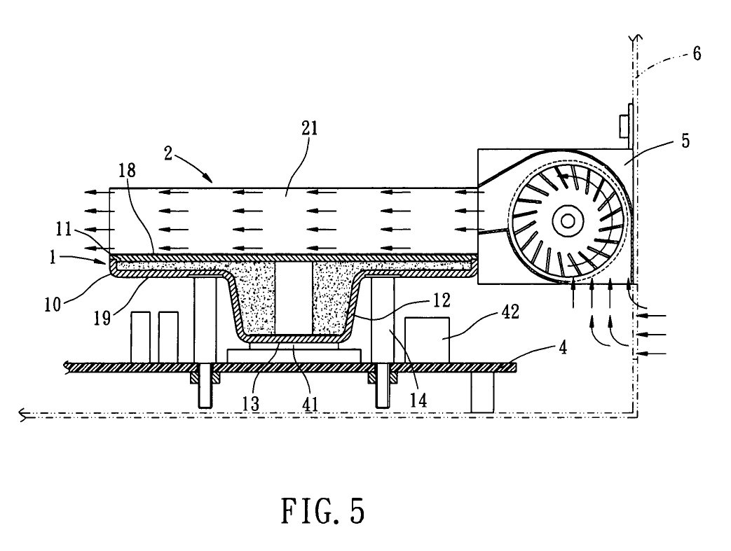

Referring to FIGS. 1 to 5, a large-area planar heat dissipation structure applied to an electronic device is illustrated. As shown, the large-area planar heat dissipation structure has a thermal conducting member 1 and a heat-sink assembly 2. As shown in FIG. 1, the thermal conducting member 1 is secured circuit board 4 to be in thermal communication with the electronic device 41 on the circuit board 4. Standing columns 14 serve as supporting and fastening members between the heat dissipation member 1 and the circuit board 4. As shown in FIG. 5, a wind generating device 5 such as a fan is installed at one side of the heat dissipation device to guide air through the heat dissipation device.

The thermal conducting member 1 is fabricated from a good thermal conductive material 10 such as metal, uniform thermal board or other material with good conductivity. The thermal conducting member 1 is in the form of a large-area plate disposed over the electronic device 41 and the peripheral devices 42 around the electronic device 41.

As shown in FIGS. 1-4, the thermal conducting member 1 includes a large-area thermal conductive 11 fabricated from the material 10, preferably a uniform thermal board. Preferably as shown in FIG. 1, the thermal conducting member 1 includes an upper large-area thermal conductive plate 18 and a lower large-area thermal conductive plate 19 joined together, and a thermal conductive base 12 protruding from a central portion of the lower thermal conductive plate 19. The thermal conductive base 12 extends downwardly in direct contact with the electronic device 41, so as to deliver the heat generated from the electronic device 41 towards the large-area heat dissipation plates 18 and 19.

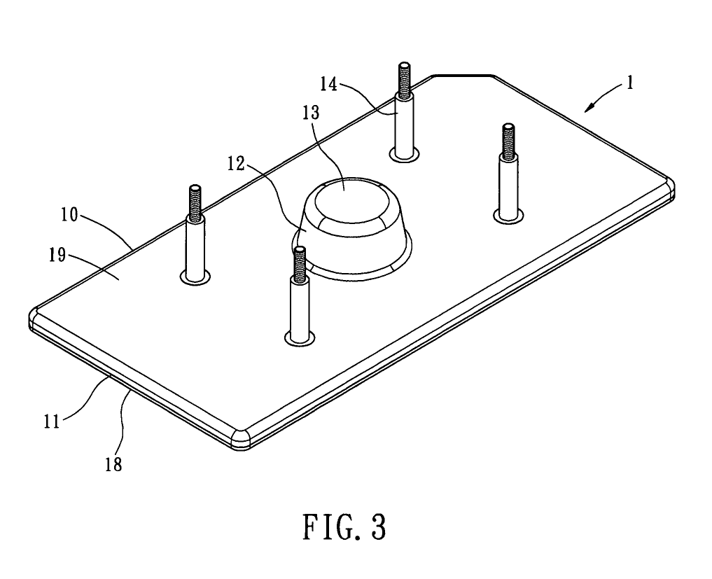

FIG. 3 shows a bottom view of the thermal conducting member 1. In the embodiment as shown in FIG. 3, the thermal conductive base 12 is in the form of a cylindrical structure. It will be appreciated that the thermal conductive base 12 can also be configured with other geometries such as tetragon, cube, ova, irregular or polygon. Preferably, the bottom of the thermal conductive base 12 is flat to provide proper contact to the electronic device 41.

The thermal conductive base 12 provides thermal communication between the thermal conductive plates 18, 19 and the electronic device 41. In addition, the columns 14 protruding from the lower thermal conductive plate 19 support and secure the thermal conducting member 1 to the circuit board at an elevated level, such that the heat dissipation surface is not limited by the available space and dimension of the electronic device 41.

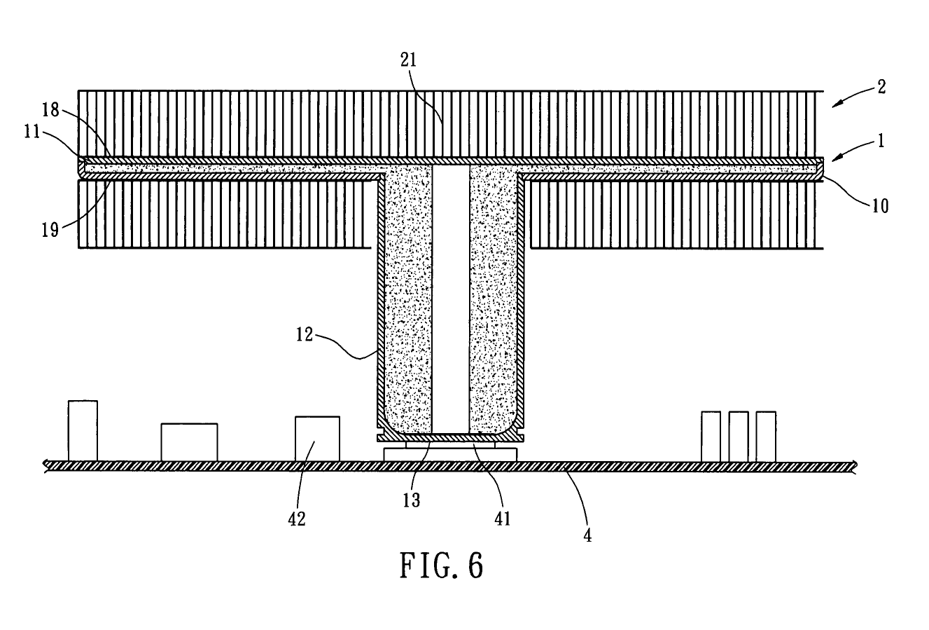

The heat sink assembly 2 includes a plurality of parallel fins 21 mounted to the upper thermal conductive plate 18. Preferably, the heat sink assembly 2 extends all over the upper heat dissipation plate 18, such that heat delivered to the upper thermal conductive plate 18 can be dissipated efficiently. Moreover, as shown in FIG. 6, there are also a plurality of parallel fins 21 extending all over the lower thermal conductive plate 19 to enhance the dissipation efficiency.

The columns 14 extending from the lower thermal conductive plate 19 terminate with screw portions to be engaged with the circuit board by a plurality of nuts as shown in FIG. 1. The columns 14 are engaged with the circuit board at locations between the electronic devices 41 and/or the peripheral devices 42. More than one column 14 is used to evenly distribute the weight of the thermal conducting member 1 and the heat sink assembly 2. The height of the columns 14 are adjusted to allow a direct contact between the bottom of the thermal conductive base 12 and the electronic device 41.

As shown in FIG. 5, a wind generating device 5 such as a fan is attached to one side of the heat dissipation structure. The wind generating device 5 generates air circulation to further improve heat dissipation performance.

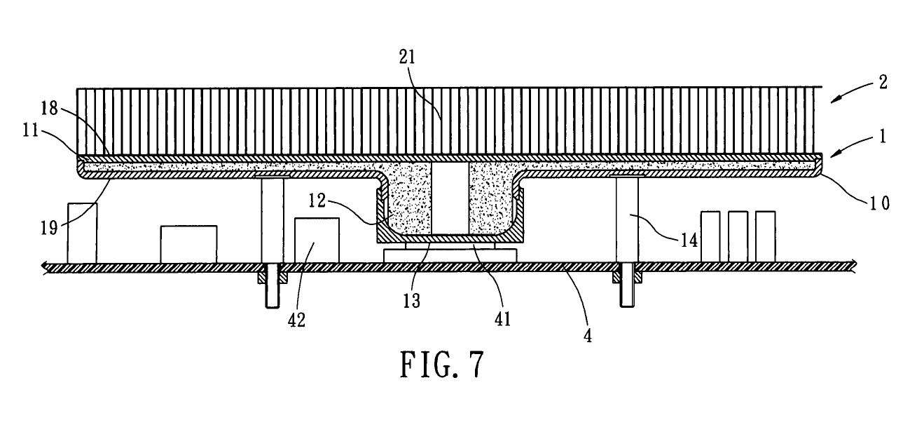

FIG. 7 shows another embodiment of a large-are heat dissipation device which includes the large-area thermal conductive plate 11 and a thermal conductive base 12 having a bottom surface conformal to a top surface of the electronic device 41. In this embodiment, the thermal conductive plate 11 and the thermal conductive base 12 are separate members joined together by processes such as soldering, fastening or interlocking. The thermal conducting member 1 is elevated over the electronic device 41, and dual thermal conductive plates 18 and 19 can also be joined together to form the thermal conductive member 1.

While the present invention has been particularly shown and described with reference to preferred embodiments thereof, it will be understood by those of ordinary skill in the art the various changes in form and details may be made therein without departing from the spirit and scope of the present invention as defined by the appended claims.

1. A large-area heat dissipation structure, comprising:
a thermal conducting member, having a large-area thermal conductive plate and a thermal conductive base protruding from a lower surface of the large-area thermal conductive plate; and
a heat sink assembly, having a plurality of fins mounted to an upper surface of the thermal conducting member.

2. The structure of claim 1, further comprising a plurality of support members extending downwardly from the lower surface of the large-area thermal conductive plate.

3. The structure of claim 2, wherein each of the support members terminates with a fastening member.

4. The structure of claim 1, wherein the large-area thermal conductive plate includes a large-area uniform thermal board.

5. The structure of claim 1, wherein the thermal conductive base includes a uniform thermal cylinder.

6. The structure of claim 1, wherein the large-area thermal conductive plate and the thermal conductive base are formed integrally.

7. The structure of claim 1, wherein the large-area thermal conductive plate includes an upper thermal conductive plate and a lower thermal conductive plate joined together.

8. The structure of claim 1, further comprising a wind generating device installed at one side of the heat sink assembly.

10. A large-area planar heat dissipation structure to dissipate heat generated from an electronic device mounted on a circuit board, the structure comprising:
a thermal conducting member, including:
a thermal conductive plate elevated over the electronic device; and
a thermal conductive base extending downwardly from the thermal conductive plate; and
a heat sink assembly attached on the thermal conductive member.

11. The structure of claim 10, wherein the thermal conducting member further comprises a plurality of support members extending downwardly therefrom.

12. The structure of claim 11, wherein the support members are fastened to the circuit board.

13. The structure of claim 11, wherein the thermal conductive base has a bottom surface conformal to a top surface of the electronic device.

14. The structure of claim 11, wherein the thermal conductive base is in direct contact with the electronic device.

15. The structure of claim 11, wherein the thermal conductive plate comprises a large-area upper plate and a large-area lower plate joined together.

16. The structure of claim 11, wherein the heat sink assembly comprises a plurality of fins.

17. The structure of claim 11, further comprising a fan installed at one side of the thermal conducting member.

18. An electronic product, comprising:
a housing;
a circuit board, enclosed in the housing;
an electronic device mounted on the circuit board; and
a heat dissipation device over the circuit board in the housing for dissipation heat generated by the electronic device, the heat dissipation device includes:
a thermal conducting member having a large-area thermal conductive plate elevated over the electronic device and a thermal conductive member extending downwardly from the thermal conductive plate, the thermal conductive base in direct contact with the electronic device; and
a heat sink assembly attached on the thermal conducting member.

19. The product of claim 18, further comprising a fan mounted at one side of the heat dissipation device in the housing.
